(19) United States
(12) Patent Application Publication
(10) Pub. No.: US 2007/0049240 A1
(43) Pub. Date: Mar. 1, 2007

(54) Satellite receiver system with time delayed signal

(75) Inventors: Jack H. King JR., Howell, MI (US); Robert J. Burnham, Novi, MI (US); Philip M. Bator, Farmington, MI (US)

Correspondence Address: VISTEON, C/O BRINKS HOFER GILSON & LIONE, PO BOX 10395, CHICAGO, IL, 60610, US

(73) Assignee: Visteon Global Technologies, Inc.

(21) Appl. No.: 11/217,901

(22) Filed: Sep. 1, 2005

(51) Int. Cl. H05K 11/02

(52) U.S. Cl. 455/345

(57) ABSTRACT

A satellite receiver system including an antenna, an amplifier, a tuner, a base band processor, and a buffer is provided. The antenna is configured to receive a satellite signal. The amplifier is in communication with the antenna and configured to generate an amplified signal based on the satellite signal. The tuner is in communication with the antenna and configured to receive the amplified signal. The tuner generates a program signal based on the amplified signal. The base band processor receives the program signal from the tuner and generates a plurality of data segments in the program signal at predefined time intervals. The base band processor stores the program signal in the buffer thereby causing a time delay in the program signal. If the satellite signal is interrupted, the tuner will continue to play out of the buffer without interruption.

### BACKGROUND

1. Field of the Invention

The present invention generally relates to a satellite receiver system.

2. Description of Related Art

Satellite radio receivers have been widely integrated into portable and vehicle based systems. Reception of the satellite signal can be interrupted when the satellite receiver system is obstructed from the broadcast satellite signal. This often occurs when a vehicle is traveling through a tunnel or a person has entered a structure that substantially occludes the satellite signal. Satellite radio broadcasts have integrated a four second transmission delay, such that a real time signal and a four second delayed signal are both transmitted simultaneously. Accordingly, the satellite receiver plays the four second delayed signal and buffers four seconds of the real time signal. If satellite signal reception is interrupted, the tuner may play the four seconds of buffered information before the user notices there has been an interruption to the satellite signal. However, after the four second interruption, the user will no longer hear the satellite programming. As the popularity of portable satellite receivers grow, the use of such devices will expand to applications where satellite signal occlusion is more frequent. Further, increased traffic congestion can increase the amount of time a vehicle may be obstructed from receiving the satellite signal. Accordingly, the built-in four second transmission delay may be insufficient for the application and satellite programming may be interrupted.

In view of the above, it is apparent that there exists a need for an improved satellite receiver system.

### SUMMARY

In satisfying the above need, as well as overcoming the enumerated drawbacks and other limitations of the related art, the present invention provides a satellite receiver system including an antenna, an amplifier, a tuner, a base band processor, and a buffer. The antenna is configured to receive a satellite signal. In communication with the antenna, the amplifier is configured to generate an amplified signal based on the satellite signal. The tuner is in communication with the amplifier and generates a program signal based on the amplified signal. The base band processor receives the program signal from the tuner and generates a plurality of short data segments in the program signal at predefined time intervals. Inserting the plurality of short data segments, lengthens the program signal in a manner that is imperceptible to the user. The base band processor stores the program signal in the buffer, thereby causing a time delay in the program signal. Over time a significant buffer can be stored. If the satellite signal is interrupted, the tuner will continue to play out of the buffer without interruption.

Further objects, features and advantages of this invention will become readily apparent to persons skilled in the art after a review of the following description, with reference to the drawings and claims that are appended to and form a part of this specification.

### BRIEF DESCRIPTION OF THE DRAWINGS

FIG. 1 is a diagrammatic view of a satellite receiver system in accordance with the present invention;

FIG. 2 is a plot of a typical program signal; and

FIG. 3 is a plot of a time delayed signal with a data segment inserted.

### DETAILED DESCRIPTION

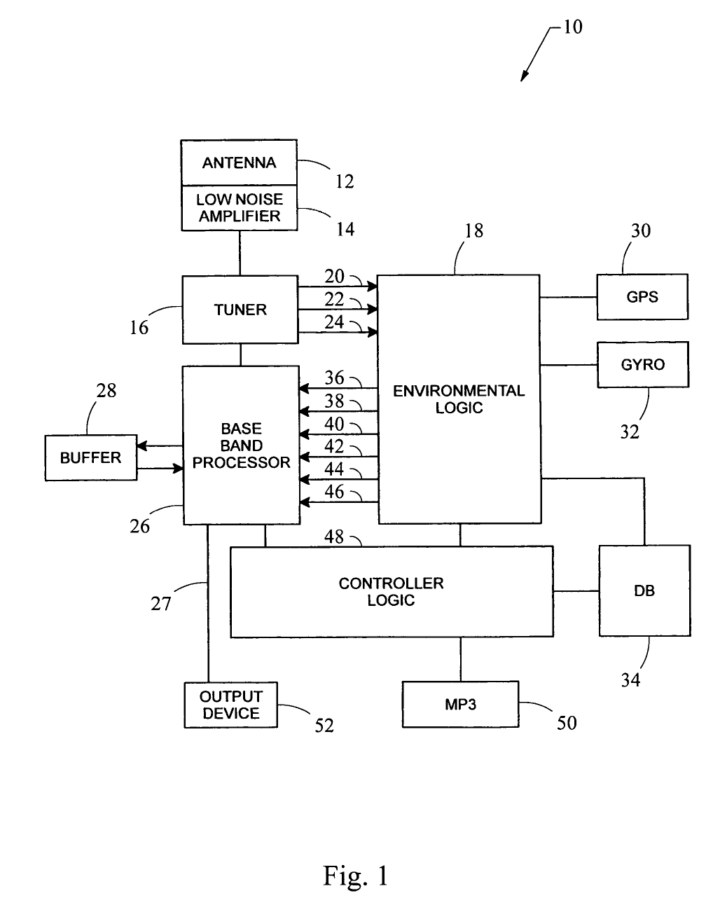

Referring now to FIG. 1, a satellite receiver system embodying the principles of the present invention is illustrated therein and designated at 10. As its primary components, the satellite receiver system 10 includes an antenna 12, a low noise amplifier 14, a tuner 16, base band processor 26, and a buffer 28. The antenna 12 is a circularly polarized antenna such as a patch antenna, a quadra filar helix antenna, or a cross dipole antenna. The antenna 12 is in communication with a low noise amplifier 14 to provide a satellite signal. The low noise amplifier 14 receives the satellite signal and is in communication with a tuner 16 to generate an audio signal. The tuner 16 provides the audio signal to the base band processor 26. The tuner 16 also provides signal information such as the automatic gain control (AGC) level 20, the bit error rate 22, and the signal to noise ratio 24, to an environmental logic block 18. The base band processor 26 receives the audio signal from the tuner 16 and generates an audio output signal 27 that is provided to an audio output device 52.

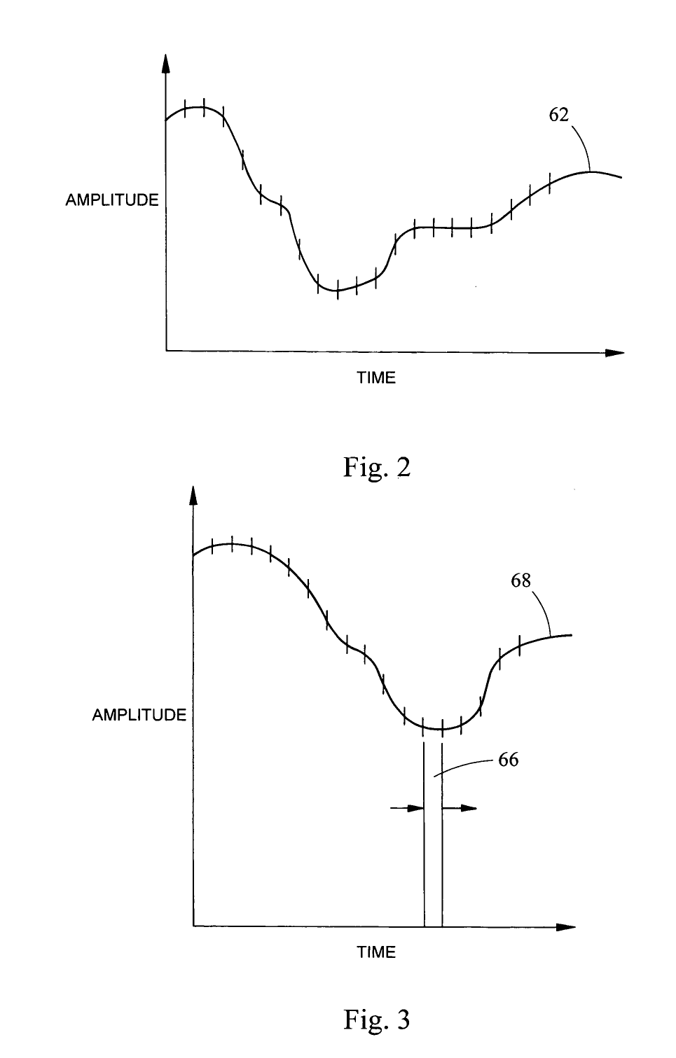

The base band processor 26 is configured to generate a data segment and insert the data segment into the program signal at predefined time intervals causing a delay in the program signal. For example, an audio signal 62 is shown in FIG. 2. The tick marks on signal 62 are representative of the sampling interval of the audio signal 62. In FIG. 3, a data segment 66 is generated and inserted in the audio signal 62 to generate a delayed audio signal 68. The data segment 66 may be generated by interpolating between the samples to the left and right of where the data segment is to be inserted. Other methods including various regression techniques (i.e. quadradic regression) may also be used to calculate the value of the data segment 66. Further, data segments may be inserted at a predefined frequency or time interval such that a delay in the signal 68 may be increased over time due to the additive effect of multiple data segments being inserted. For example, if the data segment 66 is smaller than 1/60th of a second and a few data segments are inserted each second, the delay would be imperceptible to the user. However, over many minutes a significant delay can be introduced into the signal 68 and, accordingly, a significant buffer can be generated.

Referring again to FIG. 1, a base band processor 26 is in electrical communication with a buffer 28 that is configured to store an audio signal from the base band processor 26. The base band processor 26 is configured to generate multiple data segments and insert the data segments into the audio signal thereby creating a delayed signal. The delayed signal is then stored into the buffer 28 in a first in-first out arrangement. The base band processor 26 reads out of the buffer 28 to provide the delayed audio signal as an output signal 27 to the output device 52. Alternatively, the base band processor 26 may store the audio signal directly into the buffer 28 and insert the data segments to generate a delayed audio signal after the data is read from the buffer 28 to create the audio output signal 27.

The base band processor 26 may dynamically adjust the generation of the data segments and processing of the audio signal based on signal information from the environmental logic block 18. The environmental logic block 18 may receive environmental information, such as receiver (i.e., antenna) location information from a GPS 30 and orientation information from a gyro 32. The environmental logic block 18 may use the location and orientation information along with the signal information received from the tuner 16 to determine base band processor parameters, such as AGC time constants 36, maximal ratio combiner 38, RF gain 40, buffer size 42, forward error correction 44, and data segment insertion frequency 46. Further, buffer size select and data segment insertion frequency may be varied based on the environmental information. The base band processor 26 may also be manipulated based on the signal information received provided by the tuner 16. The signal information may be used to determine whether the portable receiver is in mobile or pedestrian use. Similarly, the signal information can be processed to determine whether the portable receiver use is urban or rural.

The signal information may also be used to shut down sections of the processor, for example, to power down the forward error correction or to reduce RF gain thereby helping reduce battery consumption in an urban versus rural environment. A database 34 is provided in electrical communication with the environmental logic block 18 and includes a lookup table between tuner information, environmental information, and corresponding base band processing variables. Further, the base band processor 26 is in communication with a controller logic block 48, such that the base band processor 26 may redirect audio from an auxiliary source, such as an MP3 player 50, if the buffer 28 is depleted and the satellite signal reception has not returned.

As a person skilled in the art will readily appreciate, the above description is meant as an illustration of implementation of the principles this invention. This description is not intended to limit the scope or application of this invention in that the invention is susceptible to modification, variation and change, without departing from the spirit of this invention, as defined in the following claims.

I/We claim:

1. A satellite receiver system comprising:
an antenna configured to receive a satellite signal;
an amplifier in communication with the antenna and configured to generate an amplified signal based on the satellite signal;
a tuner in communication with the amplifier and configured to receive the amplified signal, the tuner generating a program signal based on the amplified signal;
a base band processor in communication with the tuner to receive the program signal; and
wherein the base band processor is configured to generate a plurality of data segments in the program signal at predefined time intervals and store the program signal in a buffer causing a time delay in the program signal.

2. The system according to claim 1, wherein the base band processor is configured to adjust the buffer size based on signal information.

3. The system according to claim 2, wherein the base band processor is configured to adjust the buffer size based on AGC level.

4. The system according to claim 2, wherein the base band processor is configured to adjust the buffer size based on bit error rate.

5. The system according to claim 2, wherein the base band processor is configured to adjust the buffer size based on signal to noise ratio.

6. The system according to claim 1, wherein the base band processor is configured to adjust the buffer size based on environmental information.

7. The system according to claim 6, wherein the base band processor is configured to adjust the buffer size based on receiver location.

8. The system according to claim 6, wherein the base band processor is configured to adjust the buffer size based on receiver orientation.

9. The system according to claim 1, wherein the data segment insertion frequency is based on signal information.

10. The system according to claim 9, wherein the data segment insertion frequency is based on the AGC level.

11. The system according to claim 9, wherein the data segment insertion frequency is based on bit rate error rate.

12. The system according to claim 9, wherein the data segment insertion frequency is based on signal to noise ratio.

13. The system according to claim 1, wherein the data segment insertion frequency is based on environmental information.

14. The system according to claim 13, wherein the data segment insertion frequency is based on receiver location.

15. The system according to claim 13, wherein the data segment insertion frequency is based on receiver orientation.

16. The system according to claim 1, wherein the base band processor is configured to provide a program signal from an auxiliary data source when the buffer is empty.
